(19) United States
(12) Patent Application Publication
(10) Pub. No.: US 2006/0223342 A1
(43) Pub. Date: Oct. 5, 2006

(54) Carrier element for connection terminal

(76) Inventors: Joachim Borst, Donaueschingen (DE); Klaus Bauerle, Tengen (DE); Hermann Stadler, Donaueschingen (DE); Dieter Werhan, Blumberg (DE)

Correspondence Address: NATH & ASSOCIATES, 112 South West Street, Alexandria, VA, 22314, US

(21) Appl. No.: 11/395,521

(22) Filed: Apr. 3, 2006

(30) Foreign Application Priority Data
Apr. 4, 2005 (DE) 10 2005 015 540.5

(51) Int. Cl. H05K 1/00; H01R 12/00

(52) U.S. Cl. 439/55

(57) ABSTRACT

The invention concerns a carrier element (1) for connection leads (2, 3, 4, 30), with several slots (5, 6, 7, 8) for reception of at least one connection terminals (2, 3, 4, 30) and with means of attachment (18, 20) for securing the connection leads (2, 3, 4, 30) in the slots (5, 6, 7, 8), as well as with two spaced terminal walls (10, 11).

The invention concerns a carrier element for connection leads.

Connection leads are used for the electrical connection of at least two cables or for connecting one or more cables to an electrical component, such as a printed circuit board. Many different connection leads, such as spring or screw leads, as well as connection leads with spring or soldered contacts, are known from prior art.

Connection leads, each having a terminal sleeve of insulating materials, several connection leads being connectable in series to form a multipolar lead unit on a lead strip, are known from DE 101 00 081 A1. Each lead sleeve has protruding snap-in pins on one side, which engage snap-in receptacles on the adjoining side of the adjacent terminal sleeve. A separate plastic terminal piece is provided on each side of the lead strip and/or the lead unit to flatly terminate the terminal ends comprising the snap-in receptacles or the snap-in pins. Because the terminal pieces must be designed to be complementary in shape to the corresponding terminal end of the lead strip and/or the lead unit, different connecting pieces are needed, in addition to the connection leads, to form the lead strip and/or the lead unit.

Screw connection leads connectable in series are known from DE 36 08 535 A1. The screw connection leads described feature a plastic terminal sleeve, which is provided with snap-in receptacles on one side and snap-in pins on the other side for connecting the connection leads in series. Instead of the complementary terminal pieces known from DE 101 00 081 A1, the terminal bars and/or terminal units can also be terminated by means of one-sided connection leads. These one-sided connection leads each feature an external, flat connecting surface and are designed, on the opposite side, to be complementary in shape to the respective adjacent connection leads. Accordingly, a lead strip or lead unit configured in this manner consists of three connection leads that are designed to be geometrically different from one another, i.e., two different terminal connection leads and central, identical connection leads.

The disadvantage of the known art systems is that, in addition to the connection leads, either geometrically differently shaped terminal pieces or differently shaped, one-sided connection leads are needed to form a closed connection lead strip or connection lead unit. Another disadvantage is that the connection leads have a fixed grid determined by the width of the connection leads.

The object of the invention is to create multipolar connection leads with high variability and low production costs.

This invention is achieved by the features of claim 1.

Advantageous embodiments of the invention are disclosed in the subclaims.

The invention is based on the concept of providing a carrier element for the formation of a lead strip or a lead unit, wherein the carrier element has at least one terminal-end terminal wall, preferably two terminal-end terminal walls, which terminate the lead strip or the lead unit at its terminal ends. The carrier element has several slots between the terminal walls, each for the reception of at least one connecting terminal, wherein means of attachment for securing the connecting terminals in the slots are provided. In this connection, all slots are shaped identically. This makes it possible to form a lead strip or a lead unit with only one type of connection lead.

If the connection leads are attachable to the carrier element at their face ends and/or their upper ends and/or their lower ends, lateral means of attachment can be dispensed with. As a result, the lateral surfaces of the connection leads can be shaped to be flat. No geometrically differently shaped terminal-end connection leads or geometrically differently shaped terminal pieces are needed. This significantly reduces production costs. It also simplifies assembly, because the connection leads must only be inserted into the corresponding slots on the carrier element.

Depending on the dimensions and design of the carrier element, the carrier element is suitable for connection leads of all types, shapes and sizes. Thus, for example, pluggable or solderable spring leads and screw leads can be used with the carrier element disclosed by the invention.

In the design of the invention, it is provided that partitions are provided between adjacent slots, preferably between all adjacent slots. As a result of a partition between adjacent slots, lead strips can be provided in different grids, but always with the same type of connection leads, wherein, depending on the desired grid, carrier elements with partitions of different widths are used. It is also conceivable, in this connection, that the partitions are attachable to the carrier element and not designed to be part of it. In this manner, different grid dimensions can be achieved with a carrier element by using different partition widths. Another advantage of the partitions is that the distance for leakage current and voltage arcing between adjacent connection leads is enlarged. For this purpose, the partitions should be made of insulating material.

To save material, the partitions are preferably hollow.

If all connection leads on a lead strip are to have the same grid distance from one another, all partitions are of the same width. The wider the partitions, the more effectively arcing and leakage current between adjacent connection leads are prevented.

The entire carrier element is preferably made of an insulating material, in particular, a single-piece plastic injection molded component.

In order to be able to attach the carrier element to a component, preferably a printed circuit board in a housing segment, it is advantageously provided that the carrier element features means of attachment. Snap-in mechanisms, locking mechanisms or fastening screws, in particular, may be used as means of attachment. In this connection, the means of attachment on the carrier element can be designed as snap-in receptacles for receiving snap-in means of the connection leads and/or as snap-in springs and/or as snap-in protrusions and/or as a screw threading and/or as screws and/or as locking mechanisms.

It is advantageous if the means of attachment are arranged on the carrier element in such a way that they do not interact with the lateral surfaces of the connection leads. As a result, connection leads with a smooth lateral surface can be used. In particular, the means of attachment are provided on the upper side and the lower side and/or the inner rear side of the slots. Because the connection leads are laterally delimited by either partitions or a partition and a terminal wall, laterally open connection leads, at least on one side, can be used.

For identification purposes, the connection leads can be colored differently.

The invention is explained in greater detail on the basis of the exemplary embodiments shown in the drawing, in which

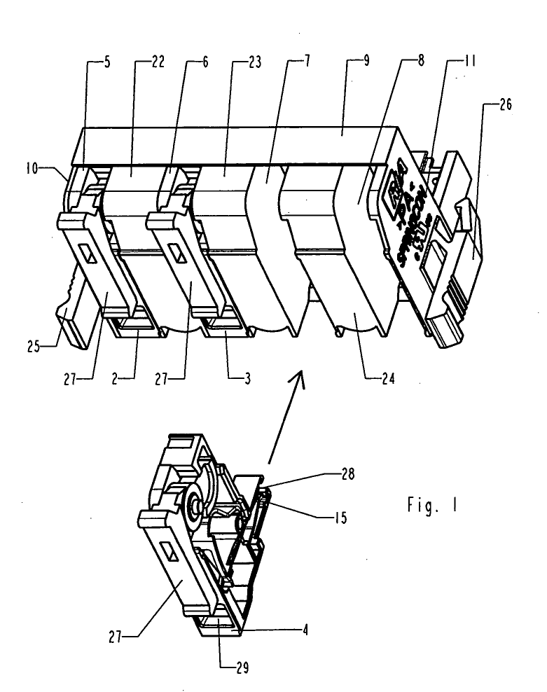

FIG. 1 shows a perspective view of a carrier element with connection leads,

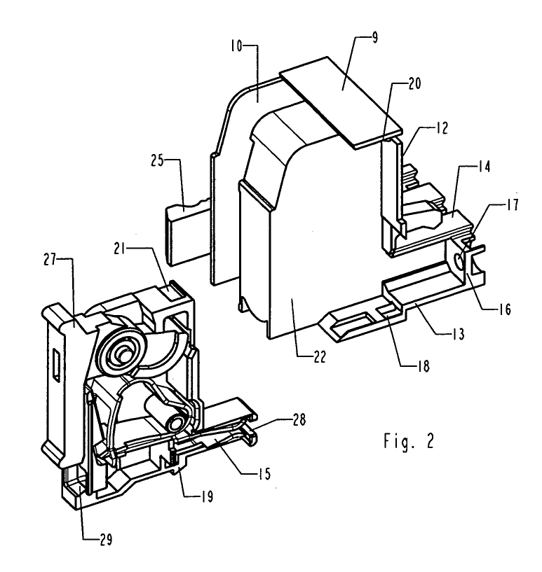

FIG. 2 shows a section through the carrier element according to FIG. 1, and

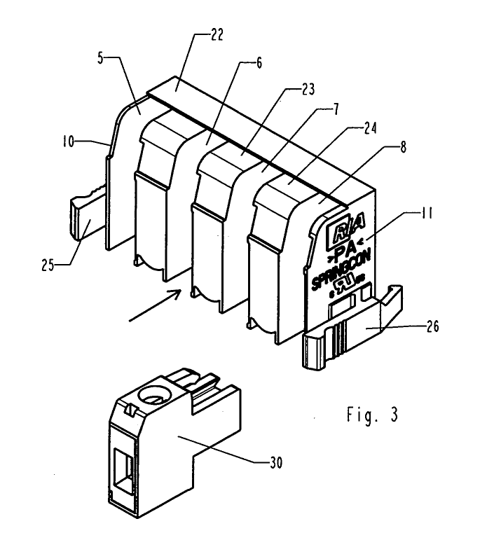

FIG. 3 shows a perspective view of a carrier element and a screw connection lead.

FIG. 1 shows a carrier element 1 with connection terminals 2, 3, 4 is shown. The carrier element 1 has four slots 5, 6, 7, 8, wherein slots 5 and 6 are occupied by connection terminals 2 and 3.

The carrier element 1 forms a frame for the connection terminals 2, 3 and 4. It consists of an upper crossbeam 9, which connects two lateral terminal walls 10, 11 with one another. The terminal walls 10, 11 extend vertically to both ends of the crossbeam 9 and terminate the carrier element 1 and, as a result, the lead strip formed by means of the carrier element 1 at their ends.

As is especially evident in FIG. 2, the terminal walls 10, 11 are not only connected to one another by the upper crossbeam 9, but also by a rear wall 12, with progresses both perpendicularly to the terminal walls 10, 11 and perpendicularly to the crossbeam 9. On the lower side of the carrier element 1, the terminal walls 10, 11 are connected to one another by a floor plate 13 progressing essentially in parallel to the crossbeam 9. A central crossbeam 14 consisting of several segments and progressing in parallel to both the crossbeam 9 and the floor plate 13 is provided between the upper crossbeam 9 and the floor plate 13. The region between the floor plate 13 and the central crossbeam 14 is part of the slots 5, 6, 7, 8 and serves as a receptacle for a connecting segment 15 of the connection lead 2, 3, 4. The terminal regions of the central crossbeam 14 and the floor plate 13 are connected to one another by means of connecting elements 16 with a continuous opening 17 for insertion of a plug pin.

A snap-in receptacle 18, into which a lower snap-in protrusion 19 of the connection terminals 2, 3, 4 is inserted, is provided in the floor plate 13 in the region of each slot 5, 6, 7 and 8. A snap-in protrusion 20, which snaps into a snap-in receptacle 21 on the upper side of the connection terminals 2, 3, 4, is provided opposite the snap-in receptacle 18 in the floor plate 13 in the upper crossbeam 9. So that the connection terminals 2, 3, 4 can snap into the slots 5, 6, 7 and 8, the crossbeam 9 is designed to be elastic to a certain extent.

Hollow partitions 22, 23, 24 are specified between the slots 5, 6, 7, 8. The width of all partitions is identical. The grid of the lead strip formed by the connection terminals 2, 3, 4 inserted into the carrier element is defined by the selection of the width of the partitions 22, 23 and 24. Each of the center slots 6, 7 is laterally delimited by two lateral partitions 22, 23, 24. In addition, the central slots 6, 7 are delimited at the top by the upper crossbeam 9 with snap-in protrusions 20, and at the rear by the floor plate 13 with snap-in receptacles 18. In the rear section, the central slots 6 and 7 are terminated by the rear wall 12, the central crossbeam 14 and the terminal elements 16 progressing perpendicularly so said central crossbeam. The connection terminals 2, 3, 4 can be attached, in a removable manner, in the slots 5, 6, 7, 8 by means of the snap-in elements 18, 19, 20, 21.

Each of the two outer slots 5 and 9 is laterally delimited by a terminal wall 10, 11 and a partition 22, 24. Otherwise, the outer slots 5, 9, like the central slots 6, 7, are delimited by the upper crossbeam 9, the floor plate 13, the rear wall 12, the central crossbeam 14 and the connecting elements 16 with openings 17.

The lateral surfaces of the partitions 22, 23, 24, as well as the interior surfaces of the terminal walls 10, 11, are smooth. The connecting terminals 2, 3, 4 are only attached at their upper and lower ends. If necessary, means of attachment can be provided, either additionally or alternatively, on the rear wall 12 of the carrier element 1.

Snap-in clamps 25, 26 for attaching the carrier element 1 to an additional component, such as a segment of a device housing or a printed circuit board, are provided externally on both terminal ends of the carrier element 1.

The connection terminals 2, 3 and 4 shown in FIGS. 1 and 2 are spring connection leads, each having an actuating element 27 as well as a connecting segment 15 with a slide-on receptacle 28 for a slide-on pin and an insertion slot 29 for insertion of a wire to be clamped disposed opposite the slide-on receptacle 28.

Another carrier element 1 is shown in FIG. 3. As is evident in the figure, the carrier element 1 shown in FIG. 3 also has two terminal walls 10 and 11, each with a snap-in clamp 25 and/or 26. The carrier element 1 contains four slots 5, 6, 7, 8 for receiving connection leads 30. The connection leads 30 are designed as screw connection leads. Partitions 22, 23, 24 are provided between the slots 5, 6, 7, 8. The wider the partitions 22, 23, 24, the larger is the grid distance between two slots 5, 6, 7, 8.

All carrier elements 1 shown in the figures are designed as one-piece, injection-mold parts made of plastic.

The smooth exterior surfaces of the terminal walls 10, 11 can be used as a writing surface.

### LIST OF REFERENCES

1 Carrier element

2 Connection terminals

3 Connection terminals

4 Connection terminals

5 Slot

6 Slot

7 Slot

8 Slot

9 Crossbeam

10 Terminal wall

11 Terminal wall

12 Rear wall

13 Floor plate

14 Central crossbeam

15 Connecting segment

16 Terminal element

17 Opening

18 Snap-in receptacles

19 Snap-in protrusion

20 Snap-in protrusion

21 Snap-in receptacle

22 Partition

23 Partition

24 Partition

25 Snap-in clamp

26 Snap-in clamp

27 Actuating element

28 Slide-on receptacle

29 Front insertion slot

30 Connection lead

1. Carrier element (1) for connection terminals (2, 3, 4, 30), with several slots (5, 6, 7, 8) for reception of at least one connection terminals (2, 3, 4, 30), with means of attachment (18, 20) for securing the connection terminals (2, 3, 4, 30) in the slots (5, 6, 7, 8), as well as with at least one, preferably two spaced terminal walls (10, 11).

2. Carrier element according to claim 1, characterized in that partitions (22, 23, 24) are provided between adjacent slots (5, 6; 6, 7; 7, 8; 8,9), preferably between all adjacent slots (5, 6; 6, 7; 7, 8; 8,9).

3. Carrier element according to claim 2, characterized in that all partitions (22, 23, 24) have the same width.

4. Carrier element according to claim 2, characterized in that at least one partitions (22, 23, 24), preferably all partitions (22, 23, 24), are hollow.

5. Carrier element according to claim 2, characterized in that the partitions (22, 23, 24) are made of an insulating material.

6. Carrier element, according to claim 1, characterized in that at least the terminal walls (10, 11), preferably the entire carrier element (1), are made of an insulating material.

7. Carrier element, according to claim 6, characterized in that the carrier element (1) is a one-piece, plastic injection-molded part.

8. Carrier element according claim 1, characterized in that the carrier element (1) [includes] means of attachment (25, 26) for attaching the carrier element (1) to a component.

9. Carrier element according to claim 1, characterized in that at least one snap-in receptacle (18) for receiving snap-in means of the connecting elements and/or at least one snap-in protrusion (20) and/or at least one screw threading and/or at least one locking mechanism is provided for attaching the connection terminals (2, 3, 4, 4 [sic], 30).

10. Carrier element according claim 1, characterized in that the slots (5, 6, 7, 8), at least in part, feature different coloring.
